(19) United States
(12) Patent Application Publication
(10) Pub. No.: US 2006/0213762 A1
(43) Pub. Date: Sep. 28, 2006

(54) Cylindrical sputtering apparatus

(75) Inventor: Xingwu Wang, Wellsville, NY (US)

Correspondence Address: CURATOLO SIDOTI CO., LPA, 24500 CENTER RIDGE ROAD, SUITE 280, CLEVELAND, OH, 44145, US

(73) Assignee: Nanoset LLC, East Rochester, NY (US)

(21) Appl. No.: 11/364,672

(22) Filed: Feb. 28, 2006

Related U.S. Application Data
(60) Provisional application No. 60/657,055, filed on Feb. 28, 2005.

(51) Int. Cl. C23C 14/32; C23C 14/00

(52) U.S. Cl. 204/192.1; 204/298.16

(57) ABSTRACT

A cylindrical sputtering target including a cylinder of a first material wherein the inner wall of the cylinder has embedded within it a pattern of small pieces of one or more different materials, whereby such target produces a spatially and compositionally uniform coating on a substrate in a cylindrical sputtering process. The molar ratio of the multiple materials in the coating composition is influenced by the size, shape, and geometrical pattern of the material pieces embedded in the inner cylinder wall.

### CROSS-REFERENCE TO RELATED APPLICATIONS

This application claims the benefit of U.S. Provisional Application No. 60/657,055 filed on Feb. 28, 2005.

### FIELD OF THE INVENTION

Apparatus for sputter coating of substrates; more particularly to such apparatus wherein the sputtering target is cylindrical; and most particularly to such apparatus wherein the inner wall of the cylindrical targets comprise multiple materials.

### BACKGROUND

Sputtering is a well-known process for applying a thin film of material to a substrate. In the sputtering process a target comprised of the material to be deposited onto the substrate is placed within a gas discharge environment and electrically connected as a cathode electrode. Ions from the gas discharge bombard the target with high enough energy to eject, that is to sputter, atoms from the target that will deposit on the substrate. The substrate is suitably located with respect to the target so that it is in the path of the sputtered atoms, whereby a coating of the target material forms on the substrate surface exposed to the impinging sputtered atoms.

Cylindrical magnetron sputtering, wherein the substrate is located within a cylindrical target, is particularly suited for coating three-dimensional complex objects, such as those used for cutting tools, biomedical de-ices, optical fibers, and so on. Cylindrical magnetron sputtering devices are well known to those of ordinary skill in the art.

By way of illustration, U.S. Pat. No. 5,069,770 discloses a sputtering process employing an enclosed sputtering target.

U.S. Pat. No. 5,529,674 discloses a modular, valveless, continuously-open, straight-through magnetron sputtering system comprising: a plurality of elongated hollow cylindrical cathode modules which define a valveless, continuously-open substrate passage.

U.S. Pat. Nos. 6,066,242 and 6,235,170 disclose a hollow cathode magnetron for sputtering target material from the inner surface of a target onto an off-spaced substrate.

U.S. Pat. No. 6,432,286 also discloses a hollow cathode magnetron.

U.S. Pat. No. 6,497,803 discloses an unbalanced plasma generating apparatus having cylindrical symmetry.

U.S. Pat. No. 6,551,477 discloses interlocking cylindrical magnetron cathodes and targets.

Published United States patent application 2001/0050225 discloses an unbalanced plasma-generating apparatus.

Published United States patent application 2002/0195336 discloses a like-polarity unbalanced planar magnetron array.

Published United States patent application 2003/0183518 discloses a sputtering cathode comprising a concave surface for receiving and supporting a sputtering target having a substantially conformal concave shape.

A cylindrical magnetron sputtering device is also described by Glocker et al in an article entitled “Nanocomposite Mo—Ti—N Coatings for Wear Resistant Applications,” Society of Vacuum Coaters, 48^{th} Annual Technical Conference Proceedings (April 2005).

Sputtered coatings have a variety of purposes such as increased hardness and wear resistance, corrosion resistance, anti-oxidation properties, and so on. Coatings of binary or ternary compounds often maximize such properties. Such compound coatings usually require an alloy target or multiple targets to acquire the required atoms in the desired molar ratios. Producing various compositions of targets by conventional metallurgical techniques is difficult. Huang and Duh describe a planar magnetron sputtering device for producing binary and ternary sputtered coatings in a paper entitled “Deposition of (Ti,Al)N Films onto Tool Steel by Reactive R.F. Magnetron Sputtering,” Society of Vacuum Coaters, 37^{th} Annual Technical Conference Proceedings (1994). Most applications mentioned above, i.e., coating three-dimensional complex objects, such as those used for cutting tools, biomedical devices, optical fibers, and so on, also require high uniformity of the coating over the whole surface of the object. Achieving such high uniformity with planer targets or with multiple cylindrical targets is difficult, especially with large and complex shaped substrates.

Provided are cylindrical sputtering targets that produce highly uniform coatings of compound materials on large and complex substrates. Also provided is a method of controlling the ratios of the materials in a compound coating produced from such cylindrical sputtering targets.

A distributed multiple material cylindrical sputtering target comprised of a cylinder of a first material wherein the inner wall of the cylinder has embedded within it a pattern of small chips or pieces of one or more additional materials is provided. In a cylindrical sputtering process, such target produces a substantially spatially uniform and substantially compositionally uniform coating on a substrate. The molar ratio of the multiple materials in the coating composition is controlled by the size, shape, and geometrical pattern of the material chips or pieces embedded in the inner cylinder wall.

### BRIEF DESCRIPTION OF THE DRAWINGS

FIG. 1 is a cross-sectional view of a prior art cylindrical magnetron sputtering device having a single cylindrical target;

FIG. 2 is a cross-sectional view of a prior art cylindrical magnetron sputtering device having two cylindrical targets;

FIG. 3A is a cross-sectional view of one embodiment of a cylindrical magnetron sputtering device having a distributed multiple material target;

FIG. 3B is a cross-sectional view of a wall section of one embodiment of the cylindrical magnetron sputtering device in FIG. 3A;

FIG. 3C is a cross sectional view of a wall section of another embodiment of the cylindrical magnetron sputtering device in FIG. 3A; and

FIG. 4 is a cross-sectional view of a another embodiment of a cylindrical magnetron sputtering device having a distributed multiple material target.

### DETAILED DESCRIPTION OF THE INVENTION

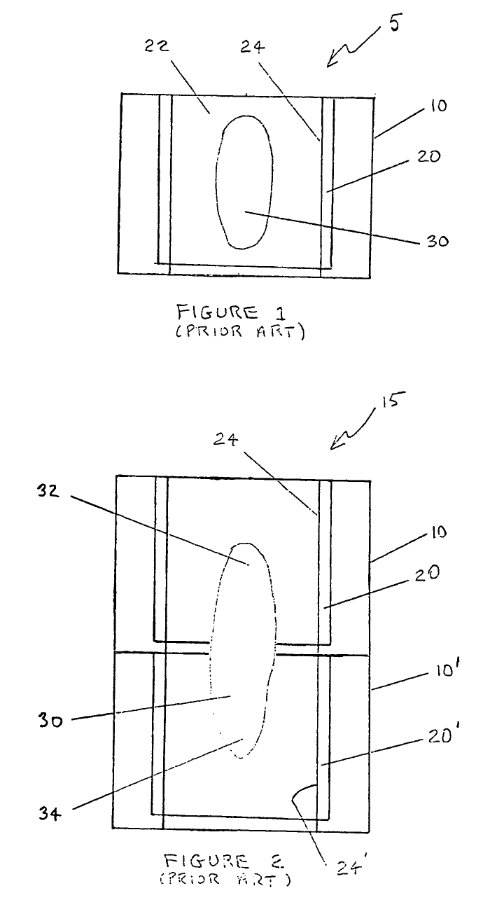

Referring now to the drawings, wherein like reference numerals designate the same or similar elements throughout the several figures, FIG. 1 shows a cross-sectional view of a cylindrical magnetron 5 as disclosed in the prior art. A cylindrical sputtering target 20 is disposed within a cylindrical cathode 10. Cylindrical sputtering apparatus are known to those skilled in the art, and therefore details of prior art cylindrical magnetron are not shown in order to simplify the drawings. For example, not shown are cooling means for cathode 10, axial magnetic fields within cylindrical magnetron 5 produced by conventional means, the plasma formed within cylindrical magnetron 5, and means for containing such plasma. Also not shown are the vacuum pumps, vacuum chamber, gas flow equipment and other means of producing a vacuum coating environment within cylindrical sputtering target 20. A substrate 30 to be coated, for example, cutting tool, biomedical device, optical fiber, and so on, is placed within the interior 22 of cylindrical sputtering device 5. Application of an appropriate voltage to cathode 10 and target 20 in the presence of a sputtering gas at the proper gas pressure produces a plasma that bombards the inner wall 24 of target 20 and thereby produces a sputtered coating of target material on substrate 30. Oxygen and/or nitrogen may also be incorporated into the sputtered coating on substrate 30 by feeding quantities of these gases into the plasma chamber in addition to the plasma gas. The amount of oxygen and/or nitrogen in the coating is determined by the flow rates of these cases relative to the flow rate of the plasma gas.

Referring now to FIG. 2, there is shown a cross-sectional view of a prior art cylindrical sputtering device 15 for co-sputtering two materials to produce a binary coating on a substrate 30. Device 15 is comprised of two cathodes 10 and 10′ within each of which are placed cylindrical targets 20 and 20′ respectively. Target 20 is comprised of a first material and target 20′ is comprise of a second material. Application of appropriate voltages to cathodes 10 and 10′ and targets 20 and 20′ in the presence of a sputtering gas at the proper gas pressure produces a plasma that bombards the inner Walls 24 and 24′ of targets 20 and 20′ respectively, and thereby produces, on substrate 30, a compound sputtered coating comprised of a compound of the first material of target 20 and the second material of target 20′.

A shortcoming of device 15 in FIG. 2 for sputtering compound coatings is that, depending on the size and shape of the substrate 30 to be coated, the coating may not be uniform, over the surface of substrate 30, in the desired molar ratio of the two different materials from targets 20 and 20′. For example, the molar ratio of the coating may be too high in the first material from target 20 at position 32 on substrate 30 and too high in the second material from target 20′ at position 34 on substrate 30.

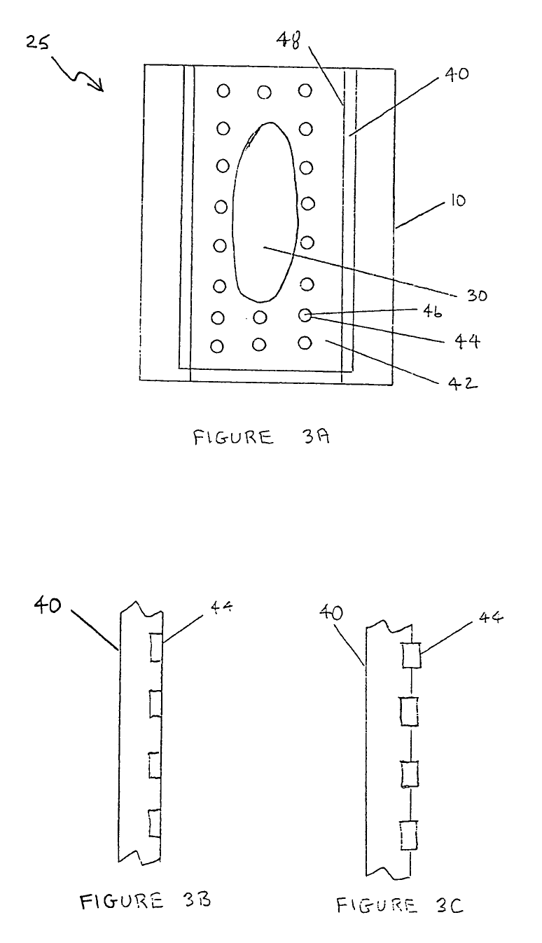

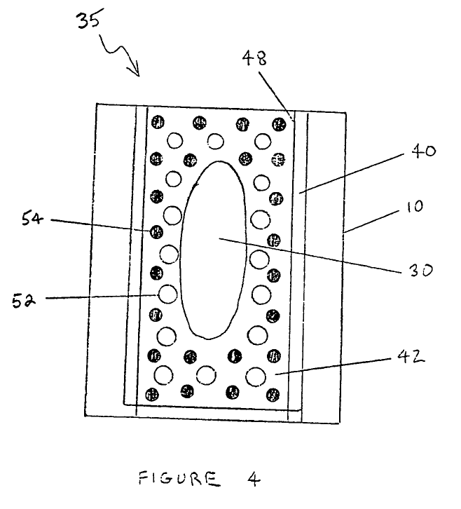

Referring now to FIG. 3A, there is shown a cross-sectional view of a cylindrical sputtering device 25 that overcomes the shortcoming of device 15 shown in FIG. 2 and described above. In cylindrical sputtering device 25 a cylindrical target 40, comprised of a first material 42, is disposed within cylindrical cathode 10. Embedded on the inside wall 48 of cylindrical target 40 is a predetermined pattern of chips or pieces 44 of at least a second material 46. This embodiment will produce a compound sputtered coating on substrate 30, comprising first material 42 atoms and second material 46 atoms. The predetermined pattern of chips or pieces 44 is such that the molar ratio of first material 42 to second material 46 in the coating sputtered onto substrate 30 is substantially uniform over the entire surface of substrate 30.

The shape of chips or pieces 44 in FIG. 3A is shown as circular, but alternatively may be any other shape such as square, oval, etc. In certain embodiments, chips or pieces 44 in FIG. 3A may have a maximum dimension in the range from about 1 millimeter to about 1 centimeter. Chips or pieces 44 may be embedded on inside wall 48 of cylindrical target 40 in a substantially uniform pattern at a predetermined density so that energy contacting such inside wall 48 will cause the generation of first material 42 atoms and second material 46 atoms in the desired molar ratio. The predetermined pattern of chips or pieces 44 may be a regular periodic pattern on wall 48 or it may be a random pattern substantially uniformly distributed on the surface of wall 48. The percentage of inside wall 48 covered by the pattern of chips or pieces 44 should be sufficient to produce the desired molar ratio of first material 42 to second material 46 in the sputtered coating. In one embodiment the percentage coverage of inner (inside) wall 48 (of FIG. 3A) by the amount of first material 42 is in the range from about 2% to about 90%. In an alternative embodiment, the percentage coverage of inner (inside) wall 48 (of FIG. 3A) by the amount of second material 46 is in the range from about 2% to about 90%.

Chips or pieces 44 may be embedded into inside wall 48 by conventional means. Referring now to FIG. 3B there is shown an enlarged cross-sectional view of one embodiment of a section of the wall of cylindrical target 40 in FIG. 3A, the section passing through a row of chips or pieces 44. In this embodiment, chips or pieces 44 were inserted into blind holes that were bored into the inner (inside) wall 48 of cylindrical target 40 and the inside wall was machined so that or pieces 44 were flush with wall 48. In another embodiment, and referring to FIG. 3C, chips or pieces 44 were inserted into blind holes that were bored into wall 4S, but were left protruding from the blind holes. As discussed herein, a blind hole is a hole that does not pass completely through the object into which it is bored.

Referring now to FIG. 4, there is shown a cross-sectional view of another embodiment, cylindrical sputtering device 35, in which chips or pieces of at least a second material 52 and a third material 54 are embedded into inside wall 48 of cylindrical target 40 composed of first material 42. This embodiment will produce a compound sputtered coating on substrate 30, comprising first material 42 atoms, second material 52 atoms, and third material 54 atoms. As with cylindrical sputtering device 25 in FIG. 3A, the molar ratios of materials 42, 52, and 54 in the sputtered coating from cylindrical sputtering device 35 in FIG. 4 may be controlled by the size and pattern of the chips or pieces of the second and third materials imbedded in wall 48 of cylindrical target 40.

Similarly an additional number of materials can be present as chips or pieces in the cylindrical target, whose number, size, and pattern control the ratio of the materials present in a sputtered coating prepared in a cylindrical device sputtering process.

The patents, patent applications, and patent application publications referenced herein, are hereby incorporated into this specification as a fully written out below.

Although the invention has been described in detail through the above detailed description and the proceeding examples, these examples are for the purpose of illustration only and it is understood that variations in modifications can be made by one skilled in the art without the departing from the spirit and scope of the invention. It should be understood that the embodiments described above are not only in the alternative, but can be combined.

What is claimed is:

1. A cylindrical magnetron sputter coating device, comprising:
a cylindrical cathode;
a cylindrical target disposed within said cylindrical cathode, said cylindrical target comprised of a first material and having an inner wall and an outer wall;
a plurality of chips or pieces disposed on said inner wall, said chips or pieces comprised of a second material.

2. The cylindrical magnetron sputter coating de ice as recited in claim 1, wherein said chips or pieces have a maximum dimension in the range from about 1 millimeter to about 1 centimeter.

3. The cylindrical magnetron sputter coating device as recited in claim 2, wherein coverage of said inner wall by the first material is in the range from about 2 percent to about 90 percent, or coverage of said inner % all by the second material chips or pieces is in the range from about 2 percent to about 90 percent.

4. The cylindrical magnetron sputter coating device as recited in claim 3, wherein said chips or pieces have a circular shape.

5. The cylindrical magnetron sputter coating device as recited in claim 3, wherein said chips or pieces have an oval shape.

6. The cylindrical magnetron sputter coating device as recited in claim 3, wherein said chips or pieces have a rectangular shape.

7. The cylindrical magnetron sputter coating de-ice as recited in claim 1, wherein said cylindrical target further contains a plurality of blind holes in said inner wall, said chips or pieces disposed within said blind holes so as to be flush with said inner wall.

8. The cylindrical magnetron sputter coating device as recited in claim 1, wherein sad cylindrical target further contains a plurality of blind holes in said inner wall, said chips or pieces disposed within said blind holes so as to protrude from said inner wall.

9. The cylindrical magnetron sputter coating device as recited in claim 3, further comprising a plurality of second chips or pieces disposed on said inner wall, said second chips or pieces comprised of a third material.

10. The cylindrical magnetron sputter coating device as recited in claim 9, wherein said second chips or pieces have a maximum dimension in the range from about 1 millimeter to about 1 centimeter.

11. The cylindrical magnetron sputter coating device as recited in claim 10, wherein a percent coverage of said inner wall by said second chips or pieces is in the range from about 2 percent to about 90 percent.

12. The cylindrical magnetron sputter coating device as recited in claim 11, wherein said chips or pieces have a circular shape.

13. The cylindrical magnetron sputter coating device as recited in claim 11, wherein said chips or pieces have an oval shape.

14. The cylindrical magnetron sputter coating device as recited in claim 11, wherein said chips or pieces have a rectangular shape.

15. A process for sputter coating, in a cylindrical magnetron sputtering device, a compound coating on a three dimensional substrate, said process comprising: providing a cylindrical target comprised of a first material, said cylindrical target having an inner wall, said inner wall having disposed thereon a plurality of chips or pieces, said chips or pieces comprised of a second material.

16. The process as recited in claim 15, wherein said chips or pieces hale a maximum dimension in the range from about 1 millimeter to about 1 centimeter.

17. The process as recited in claim 16, wherein a percent coverage of said inner wall by said chips or pieces is in the range from about 2 percent to about 90 percent.

18. The process as recited in claim 17, further comprising providing said maximum dimension and said percent coverage so as to produce a desired molar ratio of said first material to said second material in said compound coating.

19. The process as recited in claim 15, wherein said inner wall has disposed thereon a plurality of second chips or pieces, said second chips or pieces comprised of a third material.

20. A cylindrical target for a magnetron sputter coating device, comprising:
a first material having an inner wall and an outer wall;
a plurality of chips or pieces disposed on said inner wall, said chips or pieces comprised of at least a second material.

21. The cylindrical target as recited in claim 20, wherein the surface of the at least second material is flush to the surface of the inner wall of said cylindrical target.

22. The cylindrical target as recited in claim 20, wherein the surface of the at least second material protrudes from the surface of the inner wall of said cylindrical target.

23. The cylindrical target as recited in claim 20, wherein a percent coverage of said inner wall by said at least second material chips or pieces is in the range from about 2 percent to about 90 percent.

24. The cylindrical target as recited in claim 20, wherein said chips or pieces have a circular shape.

25. The cylindrical target as recited in claim 20, wherein said chips or pieces have a oval shape.

26. The cylindrical target as recited in claim 20, wherein said chips or pieces have a rectangular shape.

27. The cylindrical target as recited in claim 20, wherein said at least second material chips or pieces have a maximum dimension in the range from about 1 millimeter to about 1 centimeter.

28. The cylindrical target as recited in claim 20, further comprising a plurality of second chips or pieces disposed on said inner wall, said second chips or pieces comprised of a third material.
